(19) United States
(12) Patent Application Publication
(10) Pub. No.: US 2026/0286506 A1
(43) Pub. Date: Sep. 24, 2026

(54) TARGET ASSEMBLY AND METHOD FOR MANUFACTURING TARGET ASSEMBLY

(71) Applicant: ULVAC, INC., Kanagawa (JP)

(72) Inventors: Taiga SAKAMOTO, Kanagawa (JP); Ryota NAKAMURA, Kanagawa (JP); Taku OKUBO, Kanagawa (JP)

(21) Appl. No.: 19/478,224

(22) PCT Filed: May 20, 2024
(86) PCT No.: PCT/JP2024/018568

§ 371 Date: Oct. 23, 2025

(30) Foreign Application Priority Data
May 22, 2023 (JP) 2023-084131

(51) Int. Cl. C23C 14/34

(52) U.S. Cl. CPC C23C 14/3414

(57) ABSTRACT

A target assembly and manufacturing method are provided to prevent a drop in joining strength between a copper or copper alloy backing plate and an aluminum or aluminum alloy insert plate, and between a tungsten or molybdenum target and the insert plate, by suppressing intermetallic compound formation. The assembly includes a target of tungsten or molybdenum, a backing plate of copper or a copper alloy, and an insert material of aluminum or an aluminum alloy. The target is diffusion-bonded to the backing plate via the insert material. Diffusion bonding is mediated by a thin metal film laver positioned between the target and insert material, and between the backing plate and insert material. The film is formed of Ti, V, Cr, Nb, Pd, Ir, Pt, or an alloy containing one or more of these metals, with a thickness greater than 0.1 μm and not more than 3.0 μm.

### TECHNICAL FIELD

The present invention relates to a target assembly and to a method for manufacturing the target assembly.

### BACKGROUND ART

Diffusion bonding is known to be an effective technique for joining a sputtering target capable of withstanding high-power sputtering to a backing plate. In recent years, a large-scale sputtering target is employed, as the diameter of a wafer has increased. Particularly when the difference in coefficient of thermal expansion between the target material and the material of a backing plate is large, deformation or delamination of the backing plate from the target after diffusion bonding is a serious problem.

Meanwhile, in recent years, tungsten, having heat resistance and low resistivity, is widely used as a wiring material or an electrode material in the field of producing semiconductor devices. A study has revealed that, in the case where such a tungsten target or the like is employed, deformation after diffusion bonding is a serious problem.

In order to solve such problematic deformation, there was previously proposed a tantalum or tungsten target-copper alloy backing plate assembly in which a target formed of tantalum or tungsten is diffusion-bonded to a backing plate made of a copper alloy by the mediation of a plate having a thickness of 0.8 mm or more and formed of aluminum or an aluminum alloy serving as an insert material, wherein a diffusion bonding interface is present between respective materials (see Patent Document 1).

### PRIOR ART DOCUMENTS

### Patent Documents

Patent Document 1: Japanese Patent No. 3905301

### SUMMARY OF THE INVENTION

### Problems to be Solved by the Invention

The technique of Patent Document 1 is thought to be effective for preventing warpage. However, an intermetallic compound layer was found to be formed between the insert material (i.e., an aluminum plate or an aluminum alloy plate) and the copper alloy backing plate. It was also found that the intermetallic compound layer is very fragile, and joining strength decreases with increasing the thickness of the intermetallic compound layer. Thus, joining must be performed at low temperature, which is problematic.

From another aspect, problematically, the joining strength between tungsten and the insert material is insufficient, and variation in joining strength is large. Thus, high-temperature bonding is required, which is also problematic.

Thus, the present invention has been conceived in view of the foregoing, and an object of the invention is to provide a target assembly in which a drop in joining strength between a copper alloy backing plate and an insert material in the form of an aluminum plate or an aluminum alloy plate is prevented through suppressing formation of an intermetallic compound layer therebetween, and the joining strength between a target and the insert material can be sufficiently enhanced. Another object is to provide a method for manufacturing a target assembly (hereinafter may also be referred to as a target assembly manufacturing method).

### Means for Solving the Problems

In a first mode of the present invention to attain the aforementioned objects, there is provided a target assembly comprising a target formed of tungsten or molybdenum, a backing plate made of copper or a copper alloy, and an insert material which is an aluminum plate or an aluminum alloy plate, the target being diffusion-bonded to the backing plate by the mediation of the insert material which intervenes between the target and the backing plate, wherein diffusion bonding is achieved by the mediation of a metal thin film layer which is present between the target and the insert material and between the backing plate and the insert material, which is formed of Ti, V, Cr, Nb, Pd, Ir, Pt, or an alloy containing at least one species of the metals, and which has a thickness more than 0.1 μm and 3.0 μm or less.

A second mode of the present invention is directed to a specific embodiment of the target assembly of the first mode, wherein each of the average shear strength at the interface between the target and the insert material in the in-plane direction and the average shear strength at the interface between the insert material and the backing plate in the in-plane direction is 4 [kg/mm²] or higher.

A third mode of the present invention is directed to a specific embodiment of the target assembly of the first or second mode, wherein the ratio of the standard deviation σ of shear strength in the in-plane direction to the average shear strength in the in-plane direction, which is a coefficient of variation, is 0.15 or less.

In a fourth mode of the present invention to attain the aforementioned objects, there is provided a method for manufacturing a target assembly comprising a target formed of tungsten or molybdenum, a backing plate made of copper or a copper alloy, and an insert material which is an aluminum plate or an aluminum alloy plate, the target being diffusion-bonded to the backing plate by the mediation of the insert material which intervenes between the target and the backing plate, wherein the manufacturing method comprises disposing a metal thin film layer which is formed of Ti, V, Cr, Nb, Pd, Ir, Pt, or an alloy containing at least one species of the metals and which has a thickness more than 0.1 μm and 3.0 μm or less, between the target and the insert material or between the backing plate and the insert material or both, and subsequently, performing diffusion bonding, to thereby yield a target assembly.

A fifth mode of the present invention is directed to a specific embodiment of the target assembly manufacturing method of the fourth mode, wherein the manufacturing method comprises disposing a metal thin film layer which is formed of Ti, V, Cr, Nb, Pd, Ir, Pt, or an alloy containing at least one species of the metals and which has a thickness more than 0.1 μm and 3.0 μm or less, between the target and the insert material and between the backing plate and the insert material, and subsequently, performing diffusion bonding.

### Effects of the Invention

According to the present invention, diffusion bonding is performed, while a metal thin film layer which is formed of Ti, V, Cr, Nb, Pd, Ir, Pt, or an alloy containing at least one species of the metals and which has a thickness more than 0.1 μm and 3.0 μm or less is disposed between the target and the insert material and between the backing plate and the insert material. As a result, formation of an intermetallic compound layer between the insert material in the form of an aluminum plate or an aluminum alloy plate and the copper alloy backing plate is suppressed, to thereby prevent a drop in joining strength, and a target assembly in which the joining strength between the target and the insert material is sufficiently enhanced, and a method for manufacturing the target assembly can be provided.

### BRIEF DESCRIPTION OF THE DRAWINGS

FIG. 1 Binary diagrams of Al—Ti, Cu—Ti, and Ti—W, respectively.

FIG. 2 Binary diagrams of Al—V, Cu—V, and V—W, respectively.

FIG. 3 Binary diagrams of Al—Cr, Cr—V, and Cr—W, respectively.

FIG. 4 Binary diagrams of Al—Fe, Cu—Fe, and Fe—W, respectively.

FIG. 5 Binary diagrams of Al—Co, Co—Cu, and Co—W, respectively.

FIG. 6 Binary diagrams of Al—Ni, Cu—Ni, and Ni—W, respectively.

FIG. 7 Binary diagrams of Al—Nb, Cu—Nb, and Nb—W, respectively.

FIG. 8 Binary diagrams of Al—Pd, Cu—Pd, and Pd—W, respectively.

FIG. 9 Binary diagrams of Al—Ir, Cu—Ir, and Ir—W, respectively.

FIG. 10 Binary diagrams of Al—Pt, Cu—Pt, and Pt—W, respectively.

FIG. 11 A graph showing shear strength measurements of Examples 1 to 7 and Comparative Examples 1 to 8.

FIG. 12 A graph showing shear strength measurements of Examples 11 to 17 and Comparative Examples 11 to 18.

FIG. 13 A cross-sectional SEM image of the interface between the insert material and the backing plate in Example 3.

FIG. 14 A cross-sectional SEM image of the interface between the insert material and the backing plate in Comparative Example 2.

FIG. 15 A cross-sectional SEM image of the interface between the insert material and the backing plate in Comparative Example 5.

FIG. 16 A cross-sectional SEM image of the interface between the target and the insert material in Comparative Example 7.

### MODES FOR CARRYING OUT THE INVENTION

The target employed in the present invention is formed of tungsten or molybdenum.

Preferably, the target has a purity of 5N (99.999 mass %) or higher, a carbon (impurity) content of 30 ppm by mass or less, an oxygen (impurity) content of 30 ppm by mass or less, a relative density of 99% or higher, and a mean crystal grain size of 150 μm or less.

The backing plate employed in the present invention is made of copper or a copper alloy. No particular limitation is imposed on the material of the copper alloy backing plate, but a copper alloy such as a copper-chromium alloy or a copper-zinc alloy is preferred, since such a copper alloy has a thermal expansion coefficient smaller than that of an aluminum alloy, is less deformative, and exhibits suitable thermal conductivity. Notably, the thickness of the backing plate is 30 mm or thereabout.

As mentioned above, the target assembly of the present invention is formed through diffusion bonding of the target to the backing plate by the mediation of an insert material inserted therebetween.

As the insert material inserted between the target and the backing plate, an aluminum plate or an aluminum alloy plate having a thickness of 0.8 mm or more is preferably used, with that having a thickness of 4 to 5 mm being more preferred. One reason why the thickness of the insert material is required to be 0.8 mm or more is that the insert material is sufficiently softened at a temperature of diffusion bonding, thereby microscopically evoking breakage of surface oxide film so as to provide an active new surface, which facilitates diffusion of atoms. Another reason is that the stress attributable to difference in thermal expansion between the sputtering target and the backing plate during cooling to room temperature after diffusion bonding can be relaxed. From such a viewpoint, the insert material is preferably thick to a possible extent. However, since the total thickness of the backing plate and the insert material is restricted by the limitations of a sputtering apparatus, an increase in the thickness of the insert material imposes on a decrease in the thickness of the backing plate. When the thickness of the backing plate is reduced, cooling efficiency is impaired, which is problematic in high-power sputtering. Consequently, a certain extent of the thickness of the backing plate must be secured. Under such circumstances, an insert material having a thickness of 4 to 5 mm is preferably used. In this case, the thickness of the backing plate becomes 30 mm or thereabout. Notably, as the aluminum alloy plate, a plate of an aluminum alloy, for example, A1050 or A6061, may be used.

According to the present invention, diffusion bonding is performed, while a metal thin film layer which is formed of Ti, V, Cr, Nb, Pd, Ir, Pt, or an alloy containing at least one species of the metals is disposed between the target and the insert material and between the backing plate and the insert material. Thus, a metal thin film layer is present between the target and the insert material and between the insert material and the backing plate.

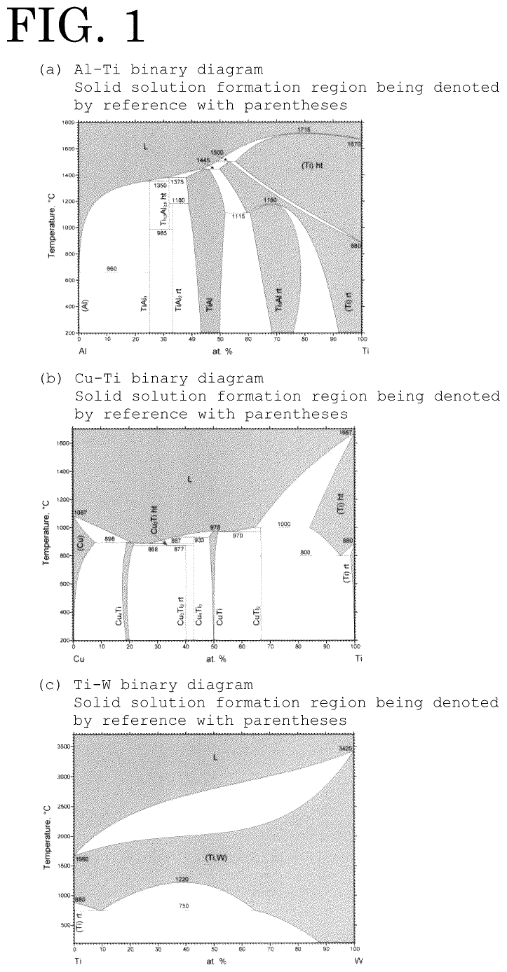

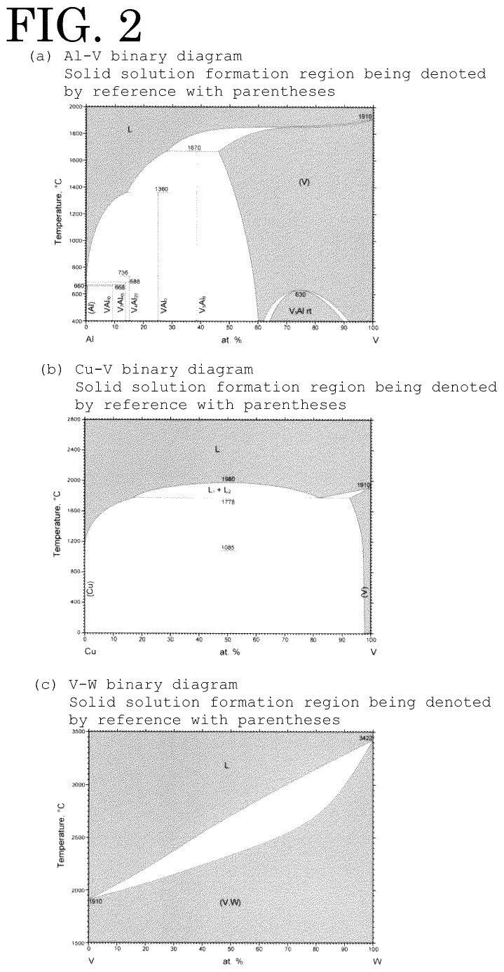

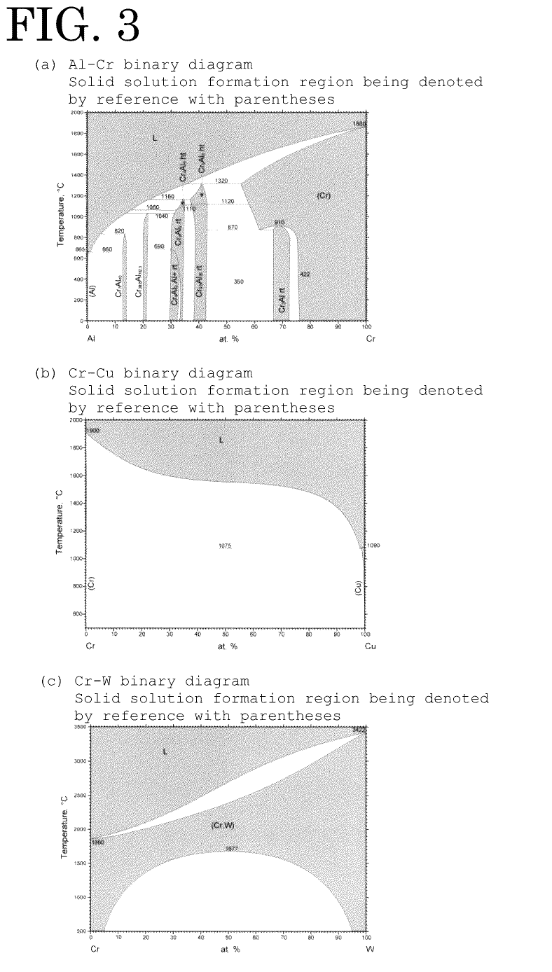

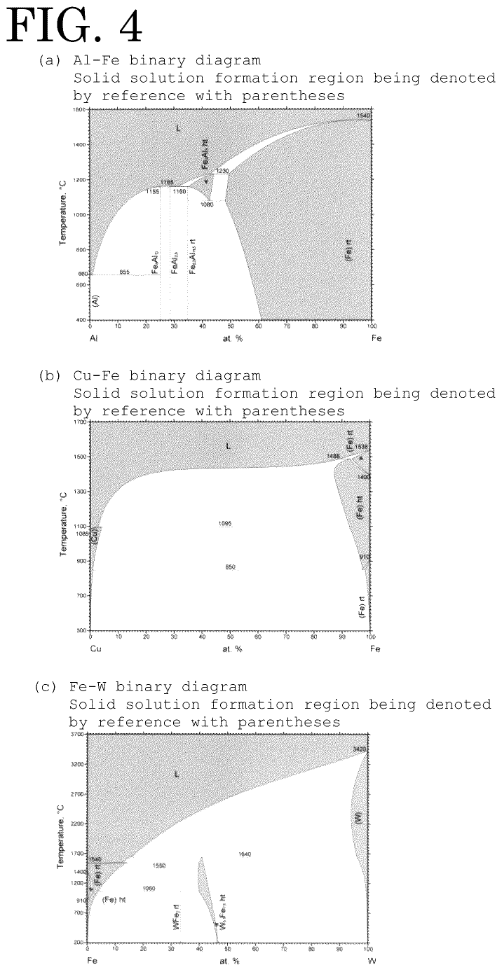

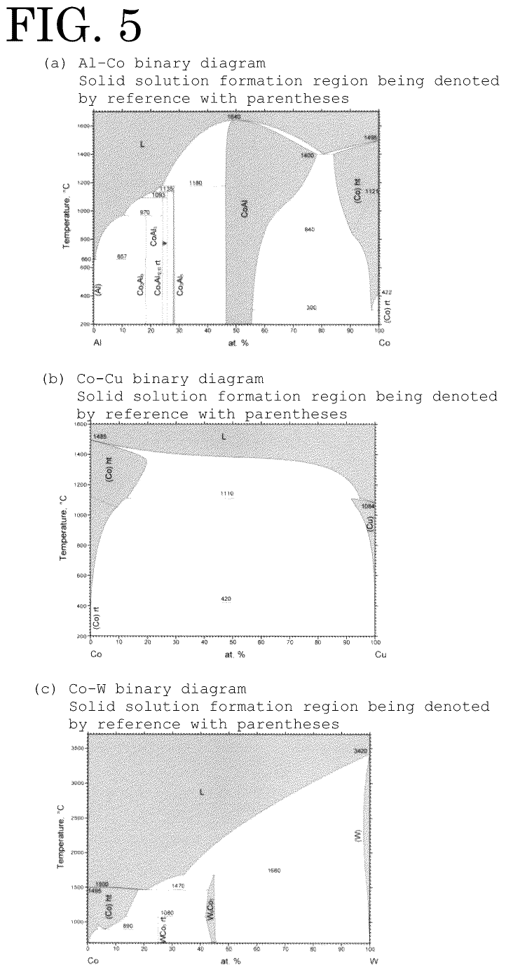

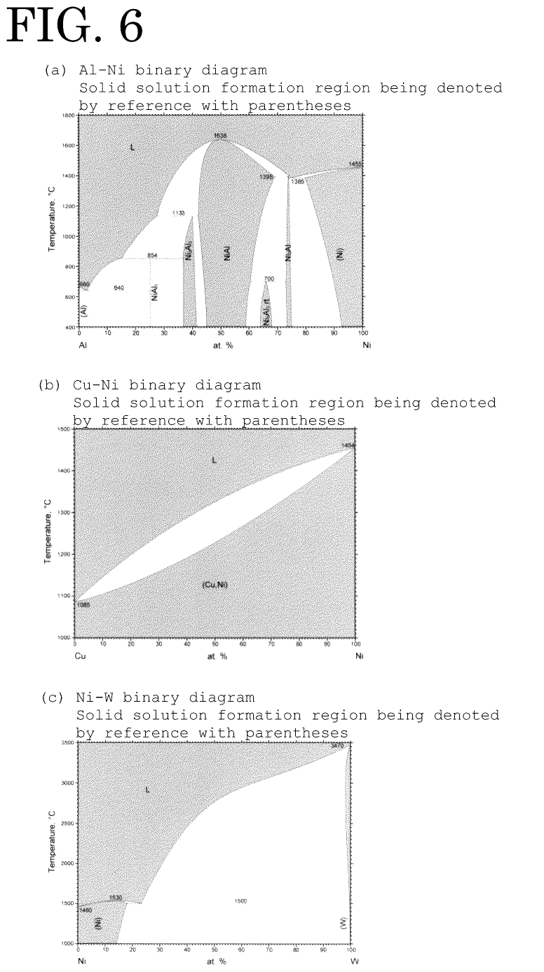

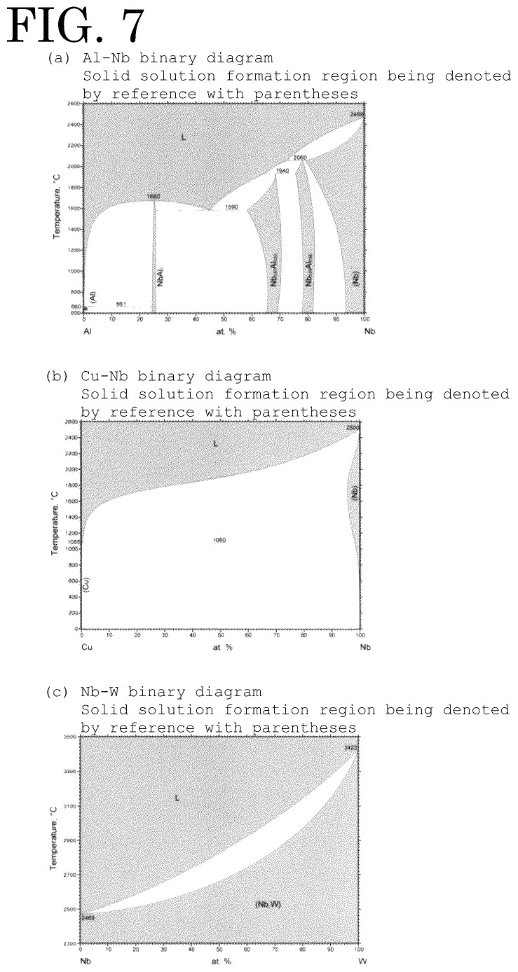

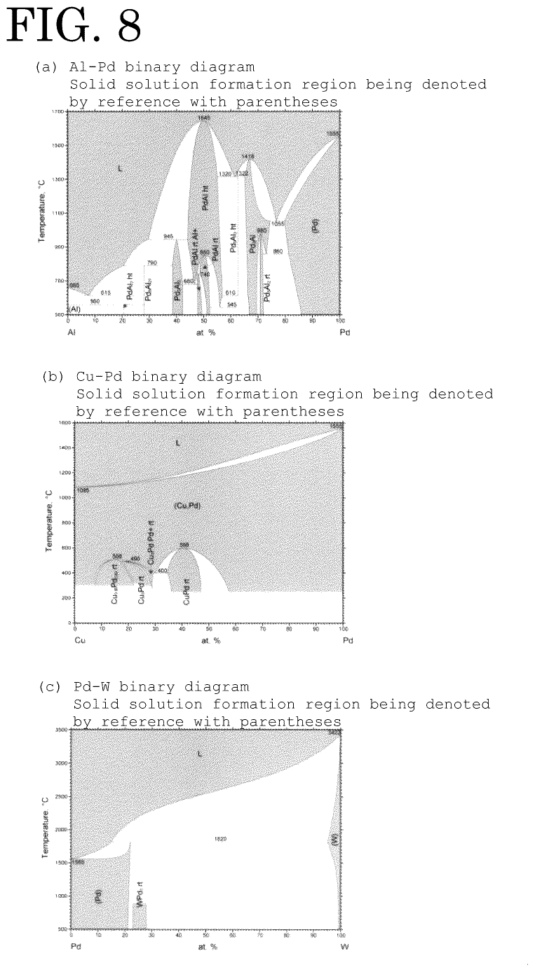

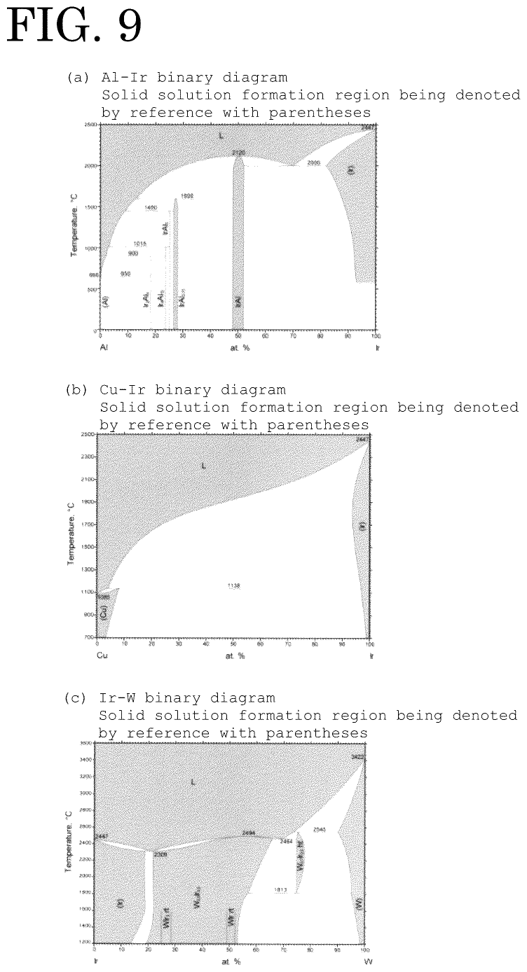

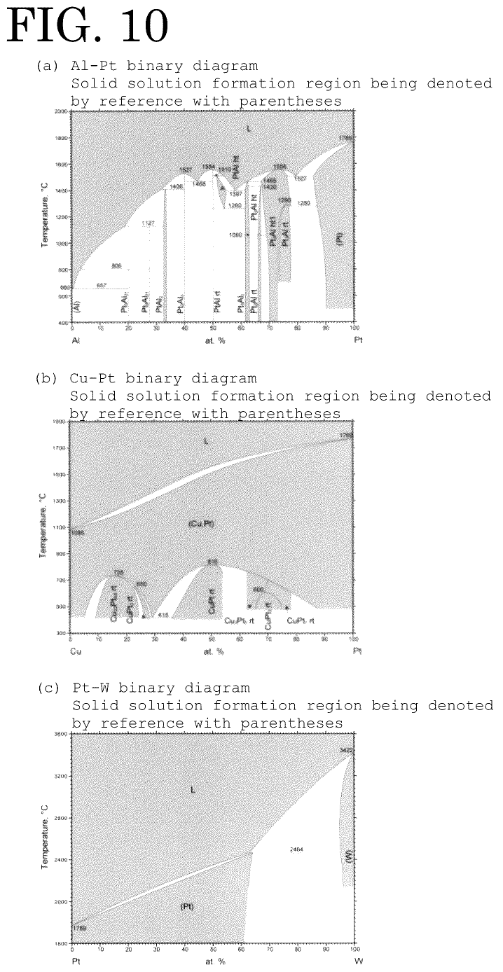

Ti, V, Cr, Fe, Co, Ni, Nb, Pd, Ir, and Pt are metal elements which can form a solid solution with any of the elements Al, Cu, and W. Therefore, the above metal elements are suited for providing a metal thin film layer to be inserted. Formation of a solid solution between two categories of metals can be proven from, for example, data shown in FIGS. 1 to 10.

FIGS. 1 to 10 each show a binary phase diagram of a system of any of Al, Cu, and W with each of the above metals. The diagrams show formation of a solid solution between a group of Ti, V, Cr, Fe, Co, Ni, Nb, Pd, Ir, and Pt, and a group of Al, Cu, and W.

Thus, the metal thin film layer formed from the above metals can enhance close adhesion between the target and the insert material and between the insert material and the backing plate, thereby achieving an enhanced joining strength. Also, the metal thin film layer disposed between the insert material (i.e., an aluminum plate or an aluminum alloy plate) and the copper or copper alloy backing plate can prevent formation of an intermetallic compound layer, which would otherwise be formed between the aluminum alloy and the copper alloy during diffusion bonding. As a result, a drop in joining strength therebetween can be prevented.

Among the group of metals Ti, V, Cr, Fe, Co, Ni, Nb, Pd, Ir, and Pt, three elements Fe, Co, and Ni are magnetic elements, which may possibly cause an adverse effect on sputtering. Thus, the three elements are not first-choice elements. Also, V is not so preferred, since V oxide is toxic. Pd, Ir, and Pt are a noble metal or a quasi-noble metal, and exhibit satisfactory functions. However, employment of these metals are preferably avoided for their high costs.

The metal thin film layer preferably has a thickness of more than 0.1 μm and 3.0 μm or less, more preferably 0.2 μm of more (i.e., more than 0.1 μm) and 3.0 μm or less. When the thickness is 0.1 μm or less, an intermetallic compound or the like is locally formed, thereby reducing joining strength, whereas when the thickness is in excess of 3.0 μm, an intermetallic compound layer may be formed between the metal thin film layer and the backing plate or the target, possibly resulting in a drop in joining strength.

Such a metal thin film layer may be formed as a coating layer on at least one joining surface between the target and the insert material and at least one joining surface between the insert material and the backing plate. No particular limitation is imposed on the method of forming the coating layer, but a physical vapor deposition technique such as sputtering, ion plating, or vacuum vapor deposition, or wet plating may be employed. The coating layer may be provided as a single layer or two or more layers. Notably, when the coating layer is provided, the joining surface is preferably subjected to a preliminary treatment such as washing with ethanol.

The metal thin film layer disposed between the target and the insert material may be identical to or different from the metal thin film layer disposed between the insert material and the backing plate. In order to prevent formation of an intermetallic compound layer between the aluminum alloy forming the insert material and the copper alloy forming the backing plate through diffusion bonding, to thereby prevent a drop in joining strength therebetween, the metal thin film layer is essentially provided only between the insert material and the backing plate.

In the target assembly fabricated through diffusion bonding, each of the joining strength at the interface between the target and the insert material and that at the interface between the insert material and the backing plate is preferably 4 [kg/mm²] or more as an average shear strength in an in-plane direction. When the joining strength is 4 [kg/mm²] or more, the target assembly sufficiently withstands against high-power sputtering. Also, the ratio of the standard deviation σ of shear strength in the in-plane direction to the average shear strength, which is a coefficient of variation, is preferably 0.15 or less. The condition corresponds to a value obtained by subtracting 3a from the average shear strength of 2.2 [kg/mm²] or greater. Under this condition, reliability in joining strength can be secured.

As mentioned above, in the target assembly manufacturing method of the present invention, the metal thin film layer is formed as a coating layer on at least one joining surface between the target and the insert material and at least one joining surface between the insert material and the backing plate, before conducting diffusion bonding. Other operations in the manufacturing method may be conducted in the same procedure as employed in a conventional target assembly manufacturing method on the basis of diffusion bonding.

Ease of formation of the intermetallic compound layer depends on the conditions of diffusion bonding. Thus, under certain joining conditions, the metal thin film layer may be provided only on the joining surface on which the intermetallic compound layer is readily formed.

No particular limitation is imposed on the mode of diffusion bonding, and it may be performed under conventionally known conditions. In one possible procedure, diffusion bonding is performed through hot isostatic pressing (HIP) at 400 to 500[° C.] for 2 to 4 hours at an application pressure of 4 to 10 [kg/mm²].

### EXAMPLES

The present invention will next be described in detail by way of the Examples and the Comparative Examples.

### Examples 1 to 7

A tungsten (W: 99.999%) target piece (disk-like plate, 460 mmφ) and a copper-zinc backing plate piece having the same size were washed with ethanol. As an insert material, a pure aluminum (A-1050) plate (thickness 5 mm) was employed, and washed in the same manner with ethanol. After washing with ethanol, the insert material was cleaned through bombardment in an Ar atmosphere (cleaning conditions: Ar atmosphere (0.7 Pa), input power (2 kW), and time (30 minutes)). Subsequently, a metal thin film layer was formed. The inter-metal thin film layer was formed through physical vapor deposition (PVD conditions: Ar atmosphere (0.4 Pa), input power (3 kW), and film formation rate (0.1 μm/minute) of a thin film made of a metal shown in Table 1 on a joining surface. Subsequently, the thus-provided assembly was put into a container via canning (vacuum: 1 Pa or less) and subjected to hot isostatic pressing (HIP), to thereby perform diffusion bonding. Diffusion bonding was performed at a temperature and applied pressure for a period of time each shown in Table 1.

### Comparative Examples 1 and 2

The procedure of the Examples was repeated, except that no metal thin film layer was provided between the target and the insert material and between the backing plate and the insert material for performing diffusion bonding, to thereby produce target assemblies. Table 1 and FIG. 14 show the results.

### Comparative Examples 3 and 4

The procedure of the Examples was repeated, except that diffusion boning was performed at a temperature falling outside a conventionally known range, to thereby produce target assemblies.

### Comparative Examples 5 to 8

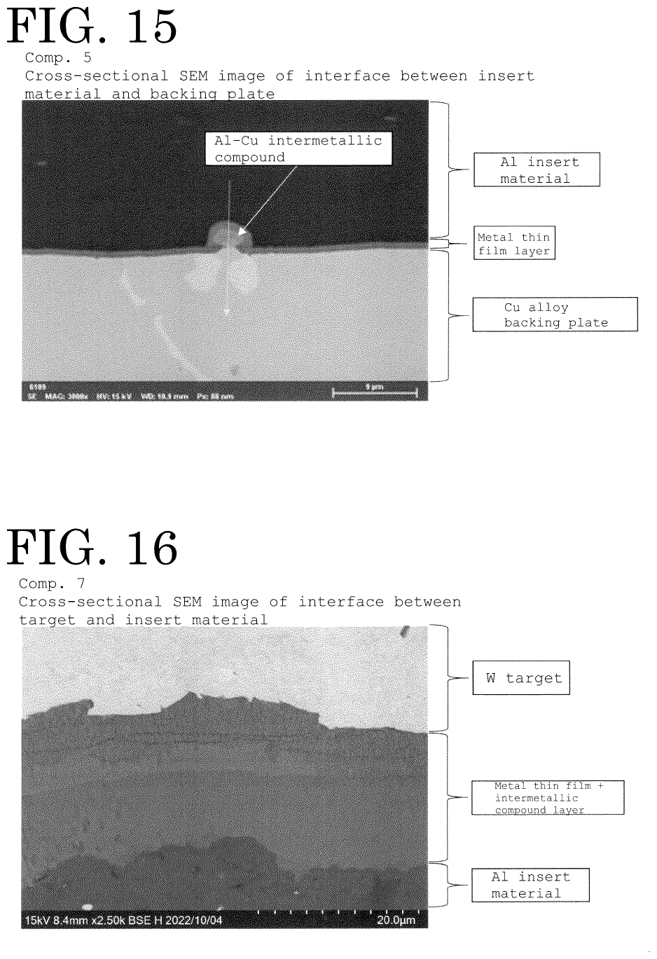

The procedure of the Examples was repeated, except that a metal thin film layer having a thickness falling outside the scope of the present invention was employed, to thereby produce target assemblies. Table 1 and FIGS. 15 and 16 show the results.

### Examples 11 to 17

As shown in Table 2, the procedure of Examples 1 to 7 was repeated, except that a molybdenum target was used instead of the tungsten target.

Table 2 shows the results.

### Comparative Examples 11 and 12

As shown in Table 2, the procedure of Comparative Examples 1 and 2 was repeated, except that a molybdenum target was used, to thereby produce target assemblies.

### Comparative Examples 13 and 14

As shown in Table 2, the procedure of Comparative Examples 3 and 4 was repeated, except that a molybdenum target was used, to thereby produce target assemblies.

### Comparative Examples 15 to 18

As shown in Table 2, the procedure of Comparative Examples 5 to 8 was repeated, except that a molybdenum target was used, to thereby produce target assemblies.

### (Method of Average Shear Strength Test)

The average shear strength at an interface between the target and the insert material in an in-plane direction and that at an interface between the insert material and the backing plate in an in-plane direction were determined through the following procedure.

### (Shear Test Method)

A shear strength of each of the test pieces which were cut from an assembly obtained through diffusion bonding at positions (the center (0 mm) and a peripheral portion (230 mm) of the 460-mmφ target) was measured at room temperature (test conditions: AUTOGRAPH AG-50kNG (product of SHIMADZU), shear speed: 5 mm/min).

Also, the standard deviation σ of shear strength, and the ratio of the standard deviation σ of shear strength in the in-plane direction to the standard deviation σ, i.e., a coefficient of variation (σ/Ave) were determined.

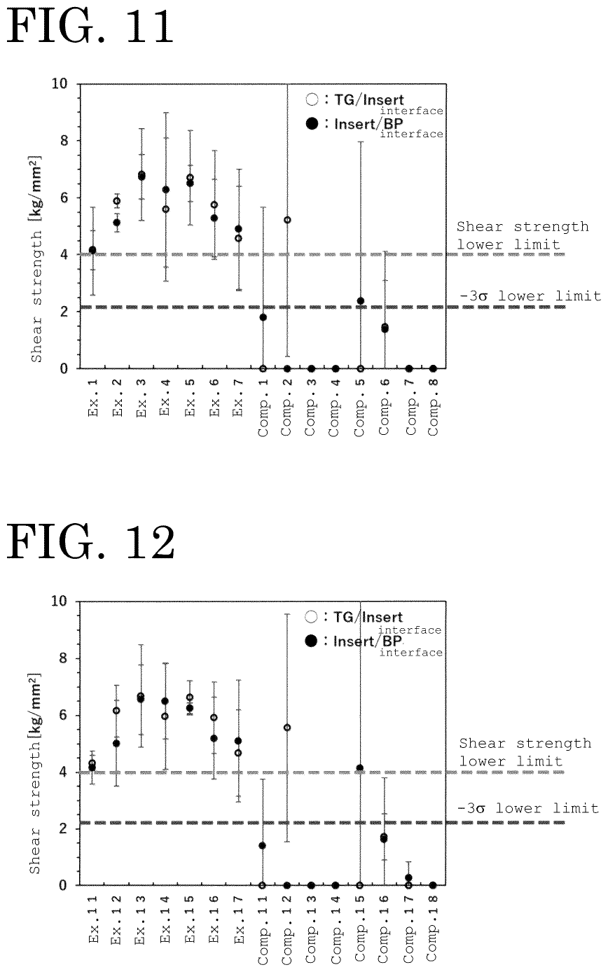

Tables 1 and 2 and FIGS. 11 and 12 show the results.

### (Formation of Compound at the Diffusion Bonding Interface)

Formation of a compound at the diffusion bonding interface was checked by observing a cut surface under a scanning electron microscope (SEM) (observation conditions: TM4000Plus (product of Hitachi Hi-Tech, acceleration voltage: 15 kV).

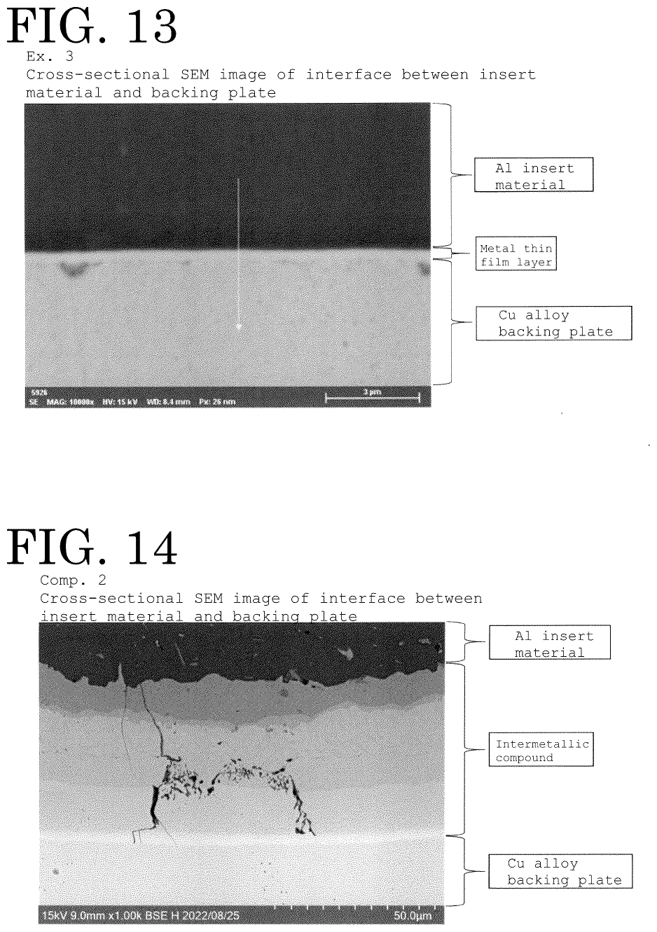

FIGS. 13 to 16 show the results.

### (Results)

In Examples 1 to 7, diffusion bonding was performed under specific conditions, while a metal thin film layer made of Ti, Cr, or Nb was disposed between the target and the insert material and between the backing plate and the insert material. Thus, formation of an intermetallic compound layer between the insert material (i.e., an aluminum plate or an aluminum alloy plate) and the copper alloy backing plate was suppressed, to thereby prevent a drop in joining strength, achieving a target assembly having a sufficiently enhanced joining strength between the target and the insert material. When the same joining temperature was employed, the joining strength between the target and the insert material was found to be about the same value in the cases of Ti and Cr, and to be a lower value in the case of Nb, as compared with the cases of Ti and Cr. Conceivably, the results are attributable to the melting point of Nb higher than that of Ti and Cr, and a small diffusion coefficient in Al and W. Further, when Al deformed through thermal expansion during diffusion bonding, Ti, which is a soft metal, can be easily deformed. However, Cr, which is a hard metal (i.e., having a low Young's modulus), may possibly be cracked. In this regard, Ti is more suitable than Cr.

In contrast, in Comparative Examples 1 and 2, diffusion bonding was performed, while no metal thin film layer was disposed between the target and the insert material and between the backing plate and the insert material. In Comparative Example 1, in which diffusion bonding was performed at low temperature so as not to form a compound, delamination occurred between the target and the insert material. In Comparative Example 2, in which diffusion bonding was performed at high temperature, a compound was formed between the insert material and the backing plate, and delamination occurred.

In Comparative Example 3, in which even a metal thin film layer was disposed, no substantial diffusion occurred due to low diffusion bonding temperature, resulting in delamination. In Comparative Example 4, a thick compound layer was formed due to excessively high diffusion bonding temperature, resulting in delamination.

In Comparative Example 5, the thickness of the metal thin film layer was too small, resulting in a large variation in joining strength.

In contrast, in Comparative Examples 6 to 8, the thickness of the metal thin film layer was too great, the compound layer became thick, resulting in delamination in the worst case due to insufficient mechanical strength.

As shown in FIG. 13; the cross-sectional SEM image of the interface between the insert material and the backing plate in Example 3, formation of an intermetallic compound layer at the joining interface between the insert material and the backing plate was not observed.

In contrast, in FIG. 14; the cross-sectional SEM image of the interface between the insert material and the backing plate in Comparative Example 2, an intermetallic compound layer was identified.

In FIG. 15; the cross-sectional SEM image of the interface between the insert material and the backing plate in Comparative Example 5, formation of an intermetallic compound, possibly due to an excessively thin metal thin film layer, was partially identified.

In FIG. 16; the cross-sectional SEM image of the interface between the target and the insert material in Comparative Example 7, formation of an intermetallic compound, possibly due to an excessively thick metal thin film layer, was identified.

TABLE 1

| | | | | | | Metal | | |
|---|---|---|---|---|---|---|---|---|
| | | | | | | film | | Manufacturing |
| | | | | | | thick- | Com- | conditions |
| | Materials | | | | | ness | pound | Temp. |
| | TG | Metal | Insert | Metal | BP | [μm] | formation | [° C.] |
| Ex. 1 | W | Ti | Al | Ti | CuZn | 0.5 | no | 400 |
| Ex. 2 | W | Ti | Al | Ti | CuZn | 0.5 | no | 450 |
| Ex. 3 | W | Ti | Al | Ti | CuZn | 0.5 | no | 500 |
| Ex. 4 | W | Ti | Al | Ti | CuZn | 0.2 | no | 500 |
| Ex. 5 | W | Ti | Al | Ti | CuZn | 3 | no | 500 |
| Ex. 6 | W | Cr | Al | Cr | CuZn | 1 | no | 450 |
| Ex. 7 | W | Nb | Al | Nb | CuZn | 1 | no | 450 |
| Comp. 1 | W | | Al | | CuZn | — | yes | 400 |
| Comp. 2 | W | | Al | | CuZn | — | yes | 500 |
| Comp. 3 | W | Ti | Al | Ti | CuZn | 0.5 | no | 300 |
| Comp. 4 | W | Ti | Al | Ti | CuZn | 0.5 | yes | 600 |
| Comp. 5 | W | Ti | Al | Ti | CuZn | 0.1 | yes | 400 |
| Comp. 6 | W | Ti | Al | Ti | CuZn | 10 | yes | 400 |
| Comp. 7 | W | Ti | Al | Ti | CuZn | 10 | yes | 500 |
| Comp. 8 | W | Ti | Al | Ti | CuZn | 500 | yes | 400 |
| | | | TG- | | | | | |
| | Manufacturing | | side av. | | | BP-side | | |
| | conditions | | shear | | | av. shear | | |
| | Time | Pressure | strength | | σ/ | strength | | σ/ |
| | [h] | [kg/mm²] | [kg/mm²] | 3σ | Ave | [kg/mm²] | 3σ | Ave |
| Ex. 1 | 4 | 4 | 4.17 | 0.69 | 0.05 | 4.13 | 1.55 | 0.12 |
| Ex. 2 | 4 | 4 | 5.89 | 0.24 | 0.01 | 5.13 | 0.31 | 0.02 |
| Ex. 3 | 4 | 4 | 6.83 | 1.61 | 0.08 | 6.74 | 0.77 | 0.04 |
| Ex. 4 | 4 | 4 | 5.59 | 2.51 | 0.15 | 6.28 | 2.71 | 0.14 |
| Ex. 5 | 4 | 4 | 6.72 | 1.66 | 0.08 | 6.51 | 0.64 | 0.03 |
| Ex. 6 | 4 | 4 | 5.75 | 1.91 | 0.11 | 5.29 | 1.36 | 0.09 |
| Ex. 7 | 4 | 4 | 4.57 | 1.83 | 0.13 | 4.90 | 2.10 | 0.14 |
| Comp. 1 | 2 | 10 | delami | — | — | 1.79 | 3.88 | 0.72 |
| Comp. 2 | 2 | 10 | 5.22 | 4.80 | 0.31 | p. delami | — | — |
| Comp. 3 | 4 | 4 | delami | — | — | delami | — | — |
| Comp. 4 | 4 | 4 | delami | — | — | delami | — | — |
| Comp. 5 | 4 | 4 | p. delami | — | — | 2.37 | 5.60 | 0.79 |
| Comp. 6 | 4 | 4 | 1.46 | 2.66 | 0.61 | 1.38 | 1.72 | 0.42 |
| Comp. 7 | 4 | 4 | p. delami | — | — | p. delami | — | — |
| Comp. 8 | 4 | 4 | delami | — | — | delami | — | — |

delami: delaminated
p. delami: partially delaminated

TABLE 2

| | | | | | | Metal | | Manufacturing |
|---|---|---|---|---|---|---|---|---|
| | | | | | | film | Com- | conditions |
| | Materials | | | | | thickness | pound | Temp. |
| | TG | Metal | Insert | Metal | BP | [μm] | formation | [° C.] |
| Ex. 11 | Mo | Ti | Al | Ti | CuZn | 0.5 | no | 400 |
| Ex. 12 | Mo | Ti | Al | Ti | CuZn | 0.5 | no | 450 |
| Ex. 13 | Mo | Ti | Al | Ti | CuZn | 0.5 | no | 500 |
| Ex. 14 | Mo | Ti | Al | Ti | CuZn | 0.2 | no | 500 |
| Ex. 15 | Mo | Ti | Al | Ti | CuZn | 3 | no | 500 |
| Ex. 16 | Mo | Cr | Al | Cr | CuZn | 1 | no | 450 |
| Ex. 17 | Mo | Nb | Al | Nb | CuZn | 1 | no | 450 |
| Comp. 11 | Mo | | Al | | CuZn | — | yes | 400 |
| Comp. 12 | Mo | | Al | | CuZn | — | yes | 500 |
| Comp. 13 | Mo | Ti | Al | Ti | CuZn | 0.5 | no | 300 |
| Comp. 14 | Mo | Ti | Al | Ti | CuZn | 0.5 | yes | 600 |
| Comp. 15 | Mo | Ti | Al | Ti | CuZn | 0.1 | yes | 400 |
| Comp. 16 | Mo | Ti | Al | Ti | CuZn | 10 | yes | 400 |
| Comp. 17 | Mo | Ti | Al | Ti | CuZn | 10 | yes | 500 |
| Comp. 18 | Mo | Ti | Al | Ti | CuZn | 500 | yes | 400 |
| | Manufacturing | | TG-side av. | | | BP-side | | |
| | conditions | | shear | | | av. shear | | |
| | Time | Pressure | strength | | σ/ | strength | | σ/ |
| | [h] | [kg/mm²] | [kg/mm²] | 3σ | Ave | [kg/mm²] | 3σ | Ave |
| Ex. 11 | 4 | 4 | 4.32 | 0.26 | 0.02 | 4.16 | 0.59 | 0.05 |
| Ex. 12 | 4 | 4 | 6.15 | 0.91 | 0.05 | 5.01 | 1.51 | 0.10 |
| Ex. 13 | 4 | 4 | 6.68 | 1.81 | 0.09 | 6.55 | 1.23 | 0.06 |
| Ex. 14 | 4 | 4 | 5.96 | 1.87 | 0.10 | 6.50 | 1.33 | 0.07 |
| Ex. 15 | 4 | 4 | 6.62 | 0.60 | 0.03 | 6.25 | 0.18 | 0.01 |
| Ex. 16 | 4 | 4 | 5.92 | 1.26 | 0.07 | 5.19 | 1.45 | 0.09 |
| Ex. 17 | 4 | 4 | 4.67 | 1.51 | 0.11 | 5.09 | 2.15 | 0.14 |
| Comp. 11 | 2 | 10 | delami | — | — | 1.41 | 2.33 | 0.55 |
| Comp. 12 | 2 | 10 | 5.55 | 4.00 | 0.24 | p. delami | — | — |
| Comp. 13 | 4 | 4 | delami | — | — | delami | — | — |
| Comp. 14 | 4 | 4 | delami | — | — | delami | — | — |
| Comp. 15 | 4 | 4 | p. delami | — | — | 4.13 | 7.71 | 0.62 |
| Comp. 16 | 4 | 4 | 1.71 | 0.81 | 0.16 | 1.62 | 2.17 | 0.45 |
| Comp. 17 | 4 | 4 | p. delami | — | — | 0.27 | 0.57 | 0.70 |
| Comp. 18 | 4 | 4 | delami | — | — | delami | — | — |

delami: delaminated
p. delami: partially delaminated

1. A target assembly comprising a target formed of tungsten or molybdenum, a backing plate made of copper or a copper alloy, and an insert material which is an aluminum plate or an aluminum alloy plate, the target being diffusion-bonded to the backing plate by a mediation of the insert material which intervenes between the target and the backing plate,
wherein diffusion bonding is achieved by the mediation of a metal thin film layer which is present between the target and the insert material and between the backing plate and the insert material, which is formed of Ti, V, Cr, Nb, Pd, Ir, Pt, or an alloy containing at least one species of metals, and which has a thickness more than 0.1 μm and 3.0 μm or less.

2. The target assembly according to claim 1, wherein each of an average shear strength at an interface between the target and the insert material in an in-plane direction and the average shear strength at the interface between the insert material and the backing plate in the in-plane direction is 4 [kg/mm²] or higher.

3. The target assembly according to claim 1, wherein a ratio of a standard deviation σ of an average shear strength at an interface between the target and the insert material in an in-plane direction to the average shear strength at the interface between the target and the insert material in the in-plane direction, and the ratio of the standard deviation σ of the average shear strength at the interface between the insert material and the backing plate in the in-plane direction to the average shear strength at the interface between the insert material and the backing plate in the in-plane direction, which are coefficients of variation, are each 0.15 or less.

4. A method for manufacturing a target assembly comprising a target formed of tungsten or molybdenum, a backing plate made of copper or a copper alloy, and an insert material which is an aluminum plate or an aluminum alloy plate, the target being diffusion-bonded to the backing plate by a mediation of the insert material which intervenes between the target and the backing plate,
wherein the method further comprises disposing a metal thin film layer which is formed of Ti, V, Cr, Nb, Pd, Ir, Pt, or an alloy containing at least one species of the metals and which has a thickness more than 0.1 μm and 3.0 μm or less, between the target and the insert material or between the backing plate and the insert material or both, and subsequently, performing diffusion bonding, to thereby yield the target assembly.

5. The method for manufacturing the target assembly according to claim 4, wherein the method further comprises disposing the metal thin film layer which is formed of Ti, V, Cr, Nb, Pd, Ir, Pt, or an alloy containing the at least one species of the metals and which has the thickness more than 0.1 μm and 3.0 μm or less, between the target and the insert material and between the backing plate and the insert material, and subsequently, performing the diffusion bonding.

6. The method for manufacturing the target assembly according to claim 4, wherein the metal thin film layer disposed between the target and the insert material or between the backing plate and the insert material or both, has at least one of an average shear strength at an interface between the target and the insert material in an in-plane direction of 4 [kg/mm²] or higher, and the average shear strength at the interface between the insert material and the backing plate in the in-plane direction of 4 [kg/mm²] or higher.
